(19) United States
(12) Patent Application Publication
(10) Pub. No.: US 2006/0290349 A1
(43) Pub. Date: Dec. 28, 2006

(54) Magnetoresistive sensor based eddy current crack finder

(75) Inventors: Jeong K. Na, Centerville, OH (US); Mark A. Franklin, Centerville, OH (US)

Correspondence Address: ARTHUR FREILICH, 9045 CORBIN AVE, #260, NORTHRIDGE, CA, 91324-3343, US

(73) Assignee: Wyle Laboratories, Inc.

(21) Appl. No.: 11/503,556

(22) Filed: Aug. 11, 2006

Related U.S. Application Data
(63) Continuation of application No. PCT/US06/24324, filed on Jun. 23, 2006.
(60) Provisional application No. 60/694,570, filed on Jun. 28, 2005.

(51) Int. Cl. G01R 33/12

(52) U.S. Cl. 324/228; 324/235

(57) ABSTRACT

An apparatus for nondestructive detecting of cracks in lapped electrically conductive upper and lower plates characterized by a probe having a square shape drive coil and a magnetoresistor sensor aligned with the longitudinal axis of the drive coil. The drive coil is intended to extend across the lap joint above the plates with the sensor mounted between the drive coil and plates. A signal generator applies periodic unipolar pulses to the drive coil.

### RELATED APPLICATION

This application is a continuation of PCT/US2006/24324 filed on 23 Jun. 2006 which claims priority based on U.S. provisional application 60/694,570 filed on Jun. 28, 2005. This application claims the benefit of both aforecited applications.

### FIELD OF THE INVENTION

This invention relates generally to nondestructive evaluation (NDE) equipment and more particularly to a giant magnetoresistive (GMR) sensor based apparatus configured to detect cracks in electrically conductive material, particularly cracks near lap joints of an aircraft fuselage.

### BACKGROUND OF THE INVENTION

U.S. Pat. No. 6,888,346 describes a probe for detecting deep flaws in thick multilayer conductive materials. The probe uses an excitation coil to induce eddy currents in conductive material oriented perpendicular to the coil's longitudinal axis. A giant magnetoresistive (GMR) sensor, surrounded by the excitation coil, is used to detect generated fields. Between the excitation coil and the GMR sensor is a highly permeable flux focusing lens which magnetically separates the GMR sensor and excitation coil and produces high flux density at the outer edge of the GMR sensor. The use of feedback inside the flux focusing lens enables cancellation of the leakage fields at the GMR sensor location and biasing of the GMR sensor to a high magnetic field sensitivity.

### SUMMARY OF THE INVENTION

The present invention is directed to an enhanced NDE probe apparatus which includes a drive coil for producing a primary magnetic field to induce eddy currents in adjacent conductive material (e.g., a metal aircraft fuselage) and a GMR sensor for detecting nonuniformities in a generated secondary magnetic field which nonuniforminities are indicative of discontinuities, or “cracks” in the conductive material.

In accordance with the present invention, the probe uses a square shape drive coil (i.e., having a substantially square cross section perpendicular to the coil's longitudinal axis) to maximize the interaction zone with a crack in the conductive material.

In accordance with a preferred embodiment, to enhance the probe's sensitivity to cracks in conductive plates adjacent to a lap joint formed by a bottom conductive plate lapped by a top conductive plate, the GMR sensor is mounted so that its axis of sensitivity is located immediately adjacent and parallel to the skin of the bottom plate. To further enhance sensitivity, the square shape drive coil is preferably constructed of minimal height, i.e., pancake fashion, and longitudinally spaced from the sensor to allow the drive coil to extend across the lap joint above the skin of the top plate.

In accordance with a further feature of the preferred embodiment, bias means are provided to produce a bias magnetic field to keep the sensor operating in the linear region of the sensor's response curve. The bias field is oriented perpendicular to the sensor axis of sensitivity to avoid interacting with the eddy current producing secondary magnetic field.

In accordance with a still further feature of a preferred embodiment, the drive coil is excited by periodic unipolar pulses (e.g., half sine wave, saw tooth pulse, square pulse) to vary the magnitude, but not the direction, of the eddy current producing primary magnetic field. As a consequence, the GMR sensor can operate unidirectionally and provide a D.C. output signal thereby minimizing the downstream signal processing requirements because unwanted A.C. components can be readily filtered.

### BRIEF DESCRIPTION OF THE FIGURES

FIG. 1 schematically illustrates the use of a square drive coil in accordance with the present invention for generating eddy currents in a conductive plate to produce a secondary magnetic field whose characteristics identify cracks in the plate;

FIG. 2 is a block diagram of a preferred GMR sensor based eddy current crack detector system consistent with FIG. 1;

FIG. 3 is a top plan view of a preferred probe in accordance with the present invention;

FIG. 4 is a side view of the probe of FIG. 3;

FIG. 5 is a top plan view showing the probe of FIG. 3 being used to detect cracks in a bottom plate of a lap joint;

FIG. 6 is a side view of the probe and lap joint as represented in FIG. 5;

FIG. 7 diagrammatically illustrates the effective interaction zone produced by a square drive coil in accordance with the present invention;

FIG. 8 illustrates a typical interaction zone of a conventional circular drive coil;

FIG. 9 is an enlarged schematic view of a preferred probe in accordance with the invention showing the physical relationship between the drive coil and the GMR sensor;

FIG. 10 is a diagrammatic view of an exemplary prior art probe showing the relationship between a drive coil and a GMR sensor;

FIG. 11 diagrammatically illustrates the utilization of a conductive trace on a circuit board supporting the GMR sensor for producing a bias magnetic field; and

FIG. 12 depicts an exemplary GMR sensor response curve.

### DETAILED DESCRIPTION

FIG. 1 schematically illustrates the basic operation of an eddy current system 10 in accordance with the present invention for detecting cracks (which term should be understood to mean any type of flaw or discontinuity) in conductive material 12, typically a metal plate 14 of an aircraft fuselage. The system 10 includes a square shape drive coil 16 which is excited by periodic unipolar pulses supplied by D.C. pulse source 18. In use, the coil 16 is positioned above plate 14 and oriented with its longitudinal axis extending substantially perpendicular to the plate. Excitation of the coil 16 by source 18 generates a primary magnetic field 20 which in turn induces eddy currents 22 in the plate 14. The eddy current flow in the plate generates a secondary magnetic field 24. If there are no cracks in the plate, the secondary magnetic field will be substantially uniform across the entire plate area. However, if the eddy current flow is disturbed by a crack, then the secondary magnetic field will exhibit nonuniformities across the plate area thereby forming tangential vector components near the crack. Such nonuniformities can be detected by a sensor located near the plate 14.

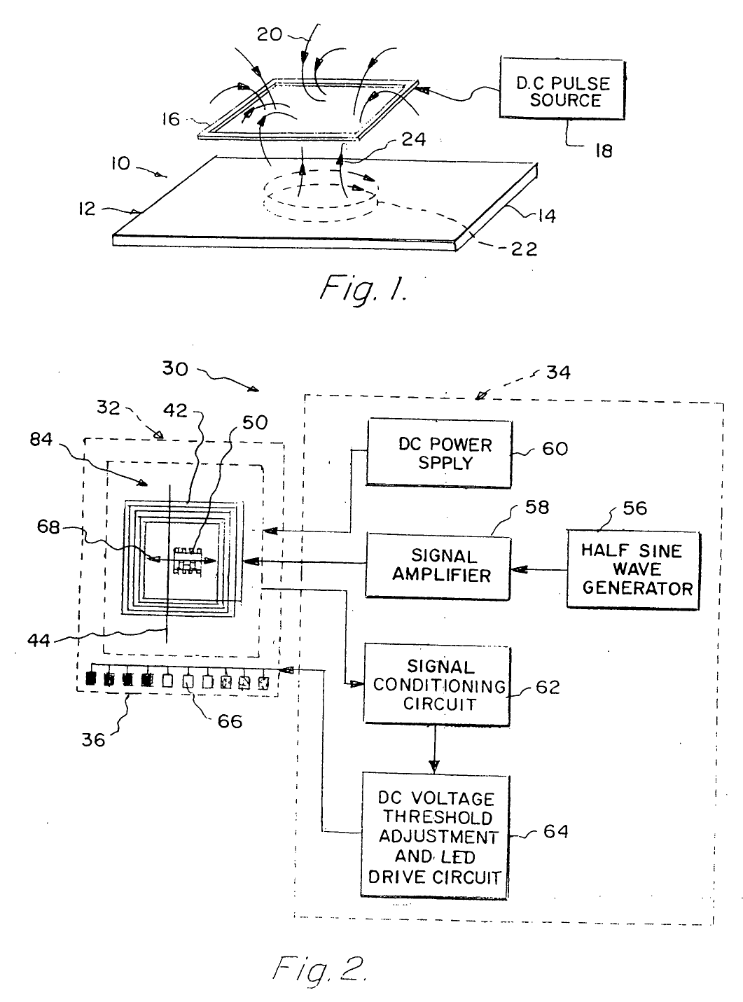

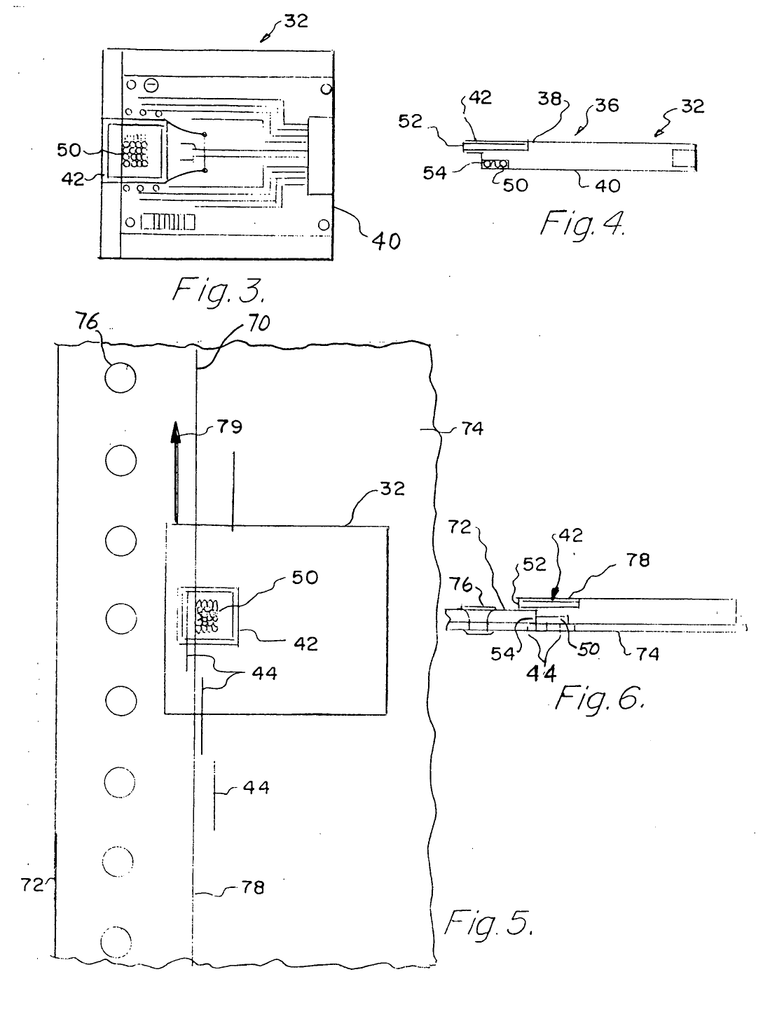

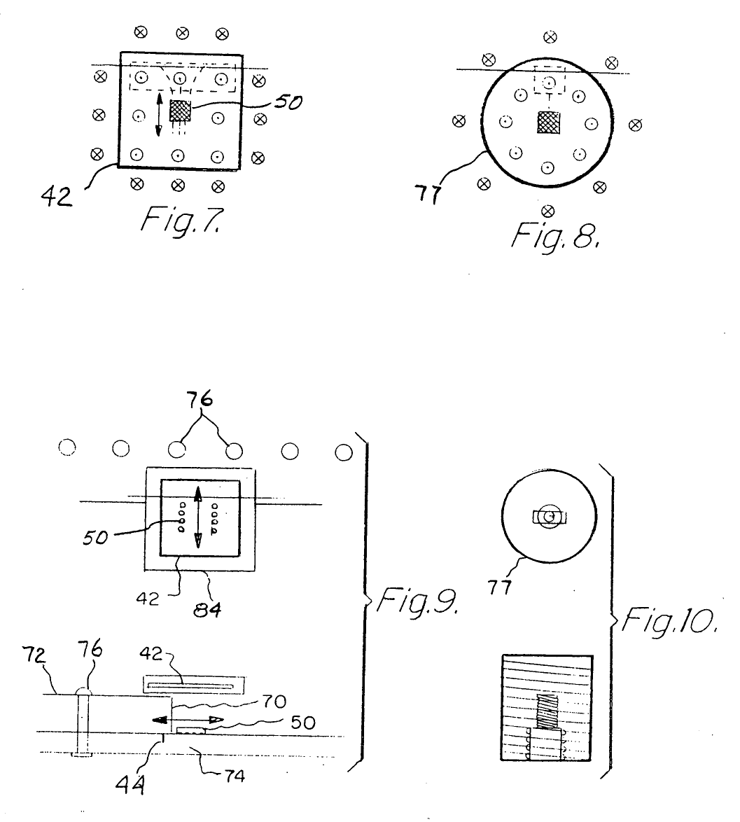

FIG. 2-4 illustrate a preferred system 30 in accordance with the invention depicted as including a probe 32 and support electronics 34. The probe 32 is comprised of a housing 36 formed by a top wall 38 and a bottom wall 40 (FIG. 4). A substantially planar drive coil 42 is mounted in the housing preferably adjacent to the underside of the top wall 38 with the longitudinal axis of the drive coil oriented essentially perpendicular to wall 38. The drive coil 42 is configured with a square cross section, or profile, (FIGS. 2, 3) to maximize the zone of interaction with cracks 44 in a conductive plate to be evaluated. The drive coil 42 is preferably pancake shaped meaning that its turns are densely packed and that its axial dimension is minimized.

FIGS. 3 and 4 show the probe 32 with a substantially planar GMR sensor 50 supported in the housing 36 on the housing bottom wall 40 which can comprise a standard circuit board. The sensor 50 is preferably aligned with the longitudinal axis of the drive coil 42 and is oriented substantially parallel to and spaced from the drive coil. Particularly note the physical relationship between the drive coil 42 and the GMR sensor 50 as shown in FIG. 4. That is, the square planar profile of the drive coil 42 is larger than that of sensor 50 so that the front edge 52 of the drive coil extends beyond the front edge 54 of sensor 50. This physical relationship facilitates detecting cracks adjacent to lap joints as will be further discussed in connection with FIGS. 5 and 6.

With reference to FIG. 2, it should be noted that the support electronics 34 includes a D.C., or unipolar, signal source 56, preferably a half sine wave generator, and signal amplifier 58 for supplying signal energy to excite drive coil 42. The support electronics 34 also includes a D.C. power supply 60 for powering the GMR sensor 50 as well as a bias winding to be discussed in connection with FIG. 11. Further, a signal conditioning circuit 62 is provided for responding to the output of sensor 50 to control circuit 64 which drives a bank of LED indicators 66 to indicate the presence and magnitude of a detected crack.

The GMR sensor 50 can be of conventional design defining a preferred axis of sensitivity 68 which is oriented perpendicular to the sensor front edge 54 (FIG. 4). The sensor 50 and drive coil 42 are arranged in such a way that a tangential vector component of the secondary magnetic field 24 extends parallel to the axis of sensitivity 68. The axis of sensitivity 68 extends essentially perpendicular to the length of a typical crack 44 in conductive material under inspection. Consequently, the sensor 50 is insensitive to both the primary magnetic field 20 (FIG. 1) generated by the drive coil 42 (FIG. 2) and the resulting secondary magnetic field 24 except when cracks exist in the material 12 under inspection. The level of the output signal from the sensor 50 can be correlated to the depth and width of a crack 44 to enable the LED drive circuit 64 to control multiple LEDs 66 which are preferably color coded to indicate the existence and quality of a crack. The circuit 64 preferably includes means for adjustably setting a threshold corresponding to the minimum crack depth to be detected.

FIGS. 5 and 6 illustrate the utilization of the probe 32 for detecting cracks 44 adjacent to a lap joint 70 (comprised of a top plate 72 and a bottom plate 74 held together by e.g., fasteners, rivets 76) which are characteristically formed in a typical aircraft fuselage. Note in FIGS. 5 and 6 that the sensor front edge 54 is held against the edge 78 of the top plate 72 as drive coil front edge 52 is moved along edge 78 (represented by scan arrow 79). Also note that the sensor 50 is positioned immediately adjacent to the skin of the bottom plate 74 whereas the substantially planar drive coil 42 is positioned to bridge both the top plate 72 and bottom plate 74. This arrangement of the square drive coil 42 and GMR sensor 50 facilitates the detection of hidden cracks adjacent the lap joint 70 of an aircraft fuselage within the foot print of the drive coil 42.

FIG. 7 schematically depicts the enlarged zone of interaction with typical plate cracks 44 (FIG. 5) achieved by using the square drive coil 42 in accordance with the invention as contrasted with the smaller interaction zone afforded by the use of a more conventional circular drive coil 77 depicted in FIG. 8. (Note: The circled dots represent magnetic lines of force going into the plane of the paper, while the circled Xs represent magnetic lines of force coming out of the plane of the paper.)

FIG. 9 schematically depicts the physical relationship between the drive coil 42 and sensor 50 which allows the sensor to touch the skin of lower plate 74 for maximum sensitivity and allows the coil 42 to bridge the lap joint 70 for maximum coverage. This arrangement in accordance with the invention (FIG. 9) is readily distinguishable from the more conventional arrangement depicted in FIG. 10.

FIG. 11 shows the inclusion of a bias winding 80 which preferably comprises a conductive trace 82 formed on the bottom wall circuit board 40 under the sensor 50. The bias winding 80 is energized from power supply 60.

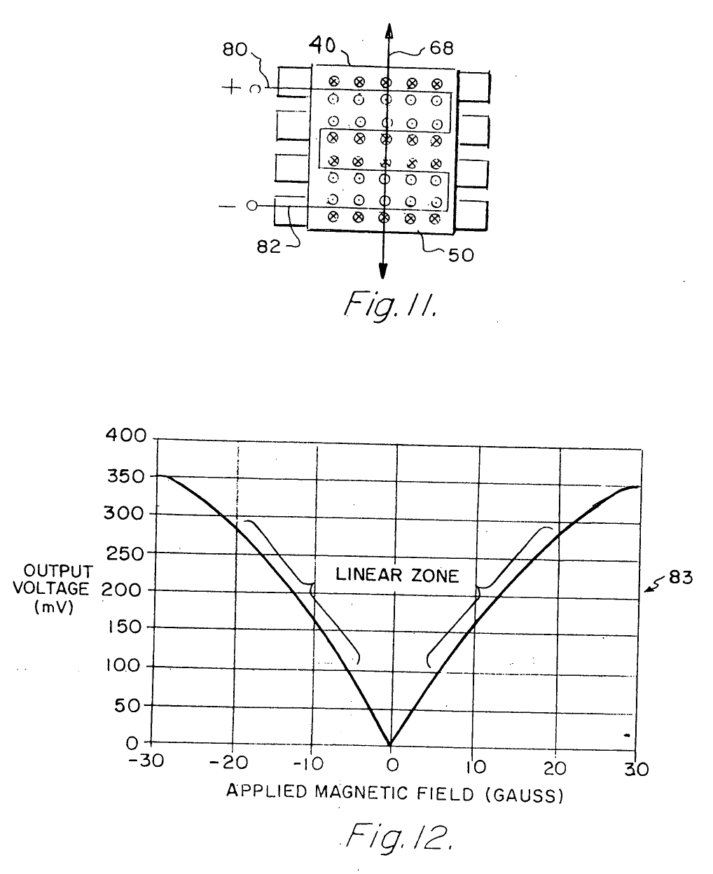

FIG. 12 shows a typical GMR sensor response curve 83. By application of an appropriate voltage across bias winding 80, the sensor 50 can be operated in a linear zone of its response curve 83 for optimum performance. The bias signal is preferably generated with DC voltage (0-5 Volts with maximum 1 AMP current) applied across the trace 82 printed on the circuit board 40. Since the trace 82 is under the GMR sensor 50 and applies a bias magnetic field perpendicular to the axis of sensitivity 68, the bias field does not interact with the secondary field crack signal but it does function to keep the background magnetic field strength above the ambient field, i.e. field attributable to the earth's magnetic field and/or fields generated by adjacent electronic equipment. In order to maximize the effect of the bias field on the GMR sensor 50, a magnetic shield 84 (FIG. 2) is preferably provided on top of the drive coil 42. When the probe 32 is placed on an aircraft skin for inspection, the skin shields any unwanted field coming from under the probe and any unwanted field coming from above the probe is shielded by shield 84. In this way, the bias field is effective to keep the sensor in the linear regions of the GMR signal response curve 83. If the bias is not correctly set (either lower section or top section of the curve), then the response to the crack signal can depart from maximum sensitivity.

It has previously been mentioned that the square drive coil 42 is preferably excited by periodic unipolar pulses. Although it is preferable to use a half sine wave generator (e.g. 56 in FIG. 2), alternatively, the unipolar pulses can be square shaped, saw tooth shaped, etc. The parameters of the excitation signal, e.g., repetition rate, pulse width, pulse amplitude can be adjusted to optimize each particular system. Inasmuch as unipolar pulses are used to create the primary magnetic field, the sensor 50 will have a unidirectional response, i.e., provide a D.C. output voltage whose level is proportional to the magnitude of the detected secondary magnetic field tangential vector components. Accordingly, the signal conditioning circuit 62 (FIG. 2) can be readily inexpensively implemented to filter out all unwanted A.C. components including intrinsic noise coming from the GMR sensor itself.

The foregoing describes a preferred crack finder in accordance with the invention particularly suited for detecting cracks in conductive plates adjacent to a lap joint. It is recognized that variations and modifications of the preferred embodiment will occur to those skilled in the art which fall within the spirit of the invention and the intended scope of the appended claims.

1. An apparatus for nondestructively detecting cracks in electrically conductive material, said apparatus comprising:
a probe;
a drive coil mounted in said probe, said drive coil defining a longitudinal axis and having a substantially square cross section oriented perpendicular to said axis; and
a magnetoresistive sensor mounted in said probe aligned with said drive coil longitudinal axis.

2. The apparatus of claim 1 further including:
a signal generator for supplying periodic unipolar pulses to said drive coil.

3. The apparatus of claim 2 wherein said signal generator supplies half sine wave pulses.

4. The apparatus of claim 2 wherein said signal generator supplies saw tooth pulses.

5. The apparatus of claim 2 wherein said signal generator supplies square pulses.

6. The apparatus of claim 1 wherein said drive coil defines a plane oriented substantially perpendicular to said longitudinal axis; and wherein
said sensor is spaced longitudinally from said drive coil plane.

7. The apparatus of claim 6 wherein said drive coil defines a planar profile larger than that of said sensor.

8. The apparatus of claim 6 wherein said drive coil defines a front edge spaced by a certain distance from said longitudinal axis and said sensor defines a front edge spaced by a lesser distance from said longitudinal axis.

9. The apparatus of claim 1 further including:
an indicator coupled to said sensor for indicating cracks in said conductive material.

10. An apparatus for nondestructively detecting cracks in electrically conductive material, said apparatus including:
drive coil means for producing a primary magnetic field to induce eddy currents in proximately placed electrically conductive material, wherein said drive coil means defines a longitudinal axis and has a substantially planar square cross section oriented perpendicular to said axis;
sensor means for detecting nonuniformities in the resultant secondary magnetic field produced by said eddy currents; and
indicator means responsive to said sensor means for indicating cracks in said electrically conductive material.

11. The apparatus of claim 10 wherein said sensor means is oriented substantially parallel to said drive coil means.

12. The apparatus of claim 10 wherein said drive coil means defines a front edge spaced by a certain distance from said longitudinal axis and said sensor means defines a front edge spaced by a lesser distance from said longitudinal axis.

13. The apparatus of claim 10 further including signal generating means for supplying periodic unipolar pulses to said drive coil means.

14. The apparatus of claim 13 wherein said signal generating means supplies half sine wave pulses.

15. The apparatus of claim 13 wherein said signal generating means supplies saw tooth pulses.

16. The apparatus of claim 13 wherein said signal generator supplies square wave pulses.

17. A method for detecting cracks in an electrically conductive substantially planar surface comprising:
a. providing a drive coil having a longitudinal axis and a substantially square planar profile oriented perpendicular to said axis;
b. providing a magnetoresistive sensor having a planar profile smaller than said drive coil square planar profile;
c. positioning said drive coil substantially parallel to and spaced from said conductive planar surface;
d. positioning said magnetoresistive sensor between said drive coil and said conductive planar surface; and
e. supplying periodic unipolar pulses to said drive coil.

18. The method of claim 17 wherein said pulses are half sine wave pulses.

19. The method of claim 17 wherein said drive coil defines a front edge and said sensor defines a front edge; and wherein
said stop of positioning said sensor locates said sensor front edge between said coil front edge and said longitudinal axis.
